(19) United States
(12) Patent Application Publication
(10) Pub. No.: US 2023/0269924 A1
(43) Pub. Date: Aug. 24, 2023

(54) SEMICONDUCTOR MEMORY DEVICE

(71) Applicant: Unisantis Electronics Singapore Pte. Ltd., Singapore (SG)

(72) Inventors: Masakazu KAKUMU, Tokyo (JP); Koji Sakui, Tokyo (JP); Nozomu Harada, Tokyo (JP)

(21) Appl. No.: 18/172,136

(22) Filed: Feb. 21, 2023

(30) Foreign Application Priority Data
Feb. 22, 2022 (WO) PCT/JP2022/007380

(51) Int. Cl. H10B 12/00; G11C 11/404; G11C 11/4096

(52) U.S. Cl. CPC H10B 12/20; G11C 11/404; G11C 11/4096

(57) ABSTRACT

Provided on a substrate are a first insulating layer; a first metal wire layer embedded therein; a second metal wire layer extending vertically on the first metal wire layer; a first n+ layer on the second metal wire layer, a semiconductor p layer on the first n+ layer, and a second n+ layer on the semiconductor p layer, each extending vertically; a gate insulating layer partially covering them; first and second electrically isolated gate conductor layers around the gate insulating layer; a second insulating layer partially covering the first and second n+ layers and the first and second gate conductor layers; a third insulating layer on the second insulating layer, partially covering the second n+ layer and the second gate conductor layer; and a fourth metal wire layer connecting to the second n+ layer via a contact hole. A fifth metal wire layer connects to the second gate conductor layer.

### CROSS REFERENCE TO RELATED APPLICATIONS

This application claims priority to PCT/JP2022/007380, filed Feb. 22, 2022, the entire content of which is incorporated herein by reference.

### BACKGROUND OF THE INVENTION

### Field of the Invention

The present invention relates to a semiconductor memory device. Description of the Related Art

In recent years, a higher degree of integration, higher performance, and lower power consumption of memory elements have been demanded in the development of the LSI (Large Scale Integration) technology.

In a common planar MOS transistor, a channel extends in the horizontal direction along the upper surface of a semiconductor substrate. In contrast, a channel of a SGT extends in a direction perpendicular to the upper surface of a semiconductor substrate (for example, see Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol.38, No.3, pp.573-578 (1991)). Therefore, when SGTs are used, the density of a semiconductor device can be increased more than when planar MOS transistors are used. Using such SGTs as selection transistors can achieve a high degree of integration of, for example, DRAM (dynamic random access memory) with a capacitor connected thereto (for example, see H. Chung, H. Kim, H. Kim, K. Kim, S. Kim, K.W. Song, J. Kim, Y.C. Oh, Y. Hwang, H. Hong, G. Jin, and C. Chung: “4F2 DRAM Cell with Vertical Pillar Transistor(VPT),” 2011 Proceeding of the European Solid-State Device Research Conference, (2011)), PCM (phase change memory) with a variable resistance element connected thereto (for example, see H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol.98, No 12, December, pp.2201-2227 (2010)), RRAM (resistive random access memory; for example, see K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3 V,” IEDM (2007)), and MRAM (magneto-resistive random access memory) whose resistance is changed by changing the direction of a magnetic spin using a current (for example, see W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp.1-9 (2015)). There is also known a capacitorless DRAM memory cell including a single MOS transistor (see M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron, ” IEEE Electron Device Letter, Vol. 31, No.5, pp.405-407 (2010)), for example. However, capacitorless DRAM has a problem in that it is greatly influenced by the capacitive coupling of a floating body with a gate electrode connected to a word line, with the result that a sufficient voltage margin cannot be secured.

Meanwhile, regarding an integrated circuit with MOS transistors each having a SGT structure, when the SGTs are connected, and if the SGTs are used for SRAM, for example, an upper electrode of each SGT is wired using a metallic material, while an n+ and a p+ located below a channel are connected using a semiconductor portion in part of a substrate (for example, see M. S. Kim, N. Harada, Y. Kikuchi, J. Boemmels. J. Mitard, T. Huynh-Bao, P. Matagne, Z. Tao, W. Li, K. Devriendt, L.-A. Rangmarsson, C. Lorant, F. Sebbai, C. Porret, E. Rosseel, A. Dangol, D. Batuk, G. Martinez-Alanis, J. Geypen, N. Jourdan, A. Sepulveda, H. Pulyalil, G. Jamieson, M. van der Veenl, L. Teugelsl, Z. El-Mekkil, E. Altamirano- Sanchezl, Y. Li2, H.Nakamura2, D. Mocutal, F. Masuoka: 2019 Symposium on VLSI Technology Digest of Technical Papers, pp.198-199 (2019)). There is also known an example in which, when SGTs are used for DRAM, for example, a lower electrode of each SGT is connected with a metal wire from above (for example, see Jin-Woo Han, Senior Member, IEEE, Jungsik Kim, Member, IEEE, Dafna Beery, K. Deniz Bozdag, Peter Cuevas, Amitay Levi, Irwin Tain, Khai Tran, Andrew J. Walker, Senthil Vadakupudhu Palayam, Antonio Arreghini, Arnaud Furnemont, and M. Meyyappan: IEEE Transaction on Electron Devices, Vol.68, No.2, pp.529-534 (2021)). There is also known a publicly disclosed example in which transistors each having a structure other than the SGT structure are used, but a metal layer is embedded in a semiconductor substrate (for example, see Myung Hee Na: Tutorials of 2020 International Electron Device Meeting (2020)). However, each of the foregoing methods has a problem in that it involves large parasitic resistance and capacitance or involves a complex process.

### SUMMARY OF THE INVENTION

The present application provides capacitorless single-transistor DRAM, specifically, a memory device with a SGT structure that solves the problem of noise due to capacitive coupling between a word line and a body, and the problem of erroneous reading or erroneous rewriting of stored data due to an unstable operation of the memory. Further, the present application provides a semiconductor memory device that has the conventional wire structure on each of opposite sides of each semiconductor memory element, and implements a high-density and high-speed MOS circuit without the need to perform a complex process of embedding a metal wire in a Si substrate (for example, see Myung Hee Na: Tutorials of 2020 International Electron Device Meeting (2020) and A. Vandooren, Z. Wu, A. Khaled, J. Franco, B. Parvais, W. Li, L. Witters, A. Walke, L. Peng, N. Rassoul, P. Matagne, H. Debruyn, G. Jamieson, F. Inoue, K. Devriendt, L. Teugels, N. Heylen, E. Vecchio, T. Zheng, D. Radisic, E. Rosseel, W. Vanherle, A. Hikavyy, B. T. Chan, G. Besnard*, W. Schwarzenbach*, G. Gaudin*, I. Radu*, B.-Y. Nguyen*, N. Waldron, V. De Heyn, S. Demuynck, J. Boemmels, J. Ryckaert, N. Collaert and D. Mocuta: 2019 Symposium on VLSI Technology Digest of Technical Papers, pp.56-57 (2019)) and so that unbalanced parasitic capacitance is not generated due to wiring of the MOSFET with the SGT structure (for example, see Koji Sakui and Tetsuo Endoh: “A Compact Space and Efficient Drain Current Design for Multipillar Vertical MOSFETs”, IEEE Transaction on Electron Devices, Vol.57, No.8, pp.1768-1773 (2021)).

To solve the foregoing problems, a semiconductor device according to the present invention includes a memory cell, the memory cell including a first insulating layer on a substrate; a first metal wire layer embedded in the first insulating layer, the first metal wire layer extending in a horizontal direction with respect to the substrate; a second metal wire layer in contact with the first metal wire layer, the second metal wire layer extending in a vertical direction with respect to the substrate and having a top surface located at a level of a top surface of the first insulating layer; a first impurity layer in contact with the second metal wire layer, the first impurity layer extending upward; a first semiconductor pillar in contact with the first impurity layer, the first semiconductor pillar extending upward; a second impurity layer continuous with a top portion of the first semiconductor pillar, the second impurity layer extending upward; a gate insulating layer covering a side face of the first semiconductor pillar, at least part of a side face of the first impurity layer, and at least part of a side face of the second impurity layer; a first gate conductor layer in contact with a side face of the gate insulating layer and in proximity to the first impurity layer; a second gate conductor layer not in contact with the first gate conductor layer but in contact with the side face of the gate insulating layer and in proximity to the second impurity layer; a second insulating layer partially covering the first impurity layer, the second impurity layer, the first gate conductor layer, and the second gate conductor layer; a third metal wire layer embedded in the first insulating layer, the third metal wire layer extending in the horizontal direction with respect to the substrate, extending in the horizontal direction in the second insulating layer, and being in contact with the first gate conductor layer; a third insulating layer partially covering the second impurity layer and the second gate conductor layer, the third insulating layer being in contact with the second insulating layer; a fourth metal wire layer connected to the second impurity layer via a contact hole formed in the third insulating layer, the fourth metal wire layer extending in the horizontal direction on or in the third insulating layer; and a fifth metal wire layer connected to the second gate conductor layer (first invention).

In the foregoing first invention, all or each of the first metal wire layer, the third metal wire layer, the fourth metal wire layer, and the fifth metal wire layer is shared by a plurality of memory cells (second invention).

In the foregoing first invention, a memory write operation is performed by controlling a voltage applied to each of the first metal wire layer, the second metal wire layer, the third metal wire layer, the fourth metal wire layer, and the fifth metal wire layer to perform an operation of generating electrons and holes in the first semiconductor pillar and/or the second impurity layer through an impact ionization phenomenon based on a current flowing between the first impurity layer and the second impurity layer or using a gate induced drain leakage current, to perform an operation of removing, from among the generated electrons and holes, the electrons or the holes that are minority carriers in the first semiconductor pillar and the second impurity layer, and to perform an operation of causing some or all of the electrons or the holes that are majority carriers in the first semiconductor pillar to remain in the first semiconductor pillar, and a memory erase operation is performed by controlling a voltage applied to each of the first metal wire layer, the third metal wire layer, the fourth metal wire layer, and the fifth metal wire layer to cause carriers remaining in the first semiconductor pillar to return to an equilibrium state (third invention).

In the foregoing first invention, one of the second metal wire layer connecting to the first impurity layer or the fourth metal wire layer connecting to the second impurity layer is a source line, and another is a bit line, one of the third metal wire layer connecting to the first gate conductor layer or the fifth metal wire layer connecting to the second gate conductor layer is a plate line, and another is a word line, and memory writing and/or erasing are/is performed by applying a voltage to each of the source line, the bit line, the plate line, and the word line (fourth invention).

In the foregoing first invention, majority carriers in the first impurity layer are electrons, and majority carriers in the first semiconductor pillar are holes (fifth invention).

In the foregoing first invention, majority carriers in the first impurity layer are holes, and majority carriers in the first semiconductor pillar are electrons (sixth invention).

In the foregoing first invention, at least one of the first gate conductor layer or the second gate conductor layer is divided into two or more regions as seen in plan view (seventh invention).

In the foregoing first invention, the first metal wire layer and the fourth metal wire layer are arranged in a direction perpendicular to an interface between the contact hole and the second impurity layer, and the first semiconductor pillar is present between the first metal wire layer and the fourth metal wire layer (eighth invention).

In the foregoing first invention, a surface of at least one of the first impurity layer or the second impurity layer is partially covered with a first metal film (ninth invention).

### BRIEF DESCRIPTION OF THE DRAWINGS

FIG. 1 is a view illustrating a cross-sectional structure of a memory device with a semiconductor element according to a first embodiment.

FIGS. 2A, 2B and 2C are views for illustrating a write operation for the memory device with the semiconductor element according to the first embodiment, storage of carriers therein immediately after an operation, and cell current.

FIGS. 3A and 3B are views for illustrating storage of hole carriers in the memory device with the semiconductor element according to the first embodiment immediately after a write operation is performed, an erase operation, and cell current.

FIGS. 4AA, 4AB and 4AC are views for illustrating a method for producing the semiconductor device according to the first embodiment.

FIGS. 4BA, 4BB and 4BC are views for illustrating the method for producing the semiconductor device according to the first embodiment.

FIGS. 4CA, 4CB and 4CC are views for illustrating the method for producing the semiconductor device according to the first embodiment.

FIGS. 4DA, 4DB and 4DC are views for illustrating the method for producing the semiconductor device according to the first embodiment.

FIGS. 4EA, 4EB and 4EC are views for illustrating the method for producing the semiconductor device according to the first embodiment.

FIGS. 4FA, 4FB and 4FC are views for illustrating the method for producing the semiconductor device according to the first embodiment.

FIGS. 4GA, 4GB and 4GC are views for illustrating the method for producing the semiconductor device according to the first embodiment.

FIGS. 4HA, 4HB and 4HC are views for illustrating the method for producing the semiconductor device according to the first embodiment.

FIGS. 41A, 4IB and 4IC are views for illustrating the method for producing the semiconductor device according to the first embodiment.

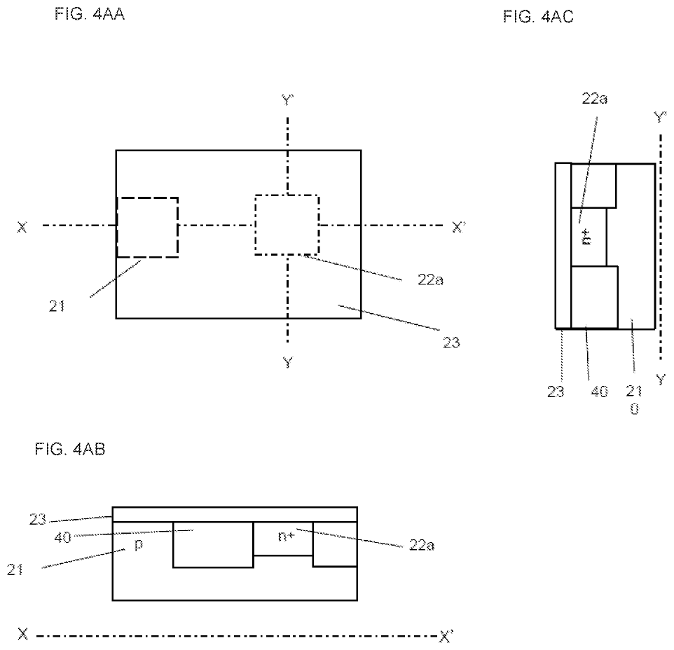

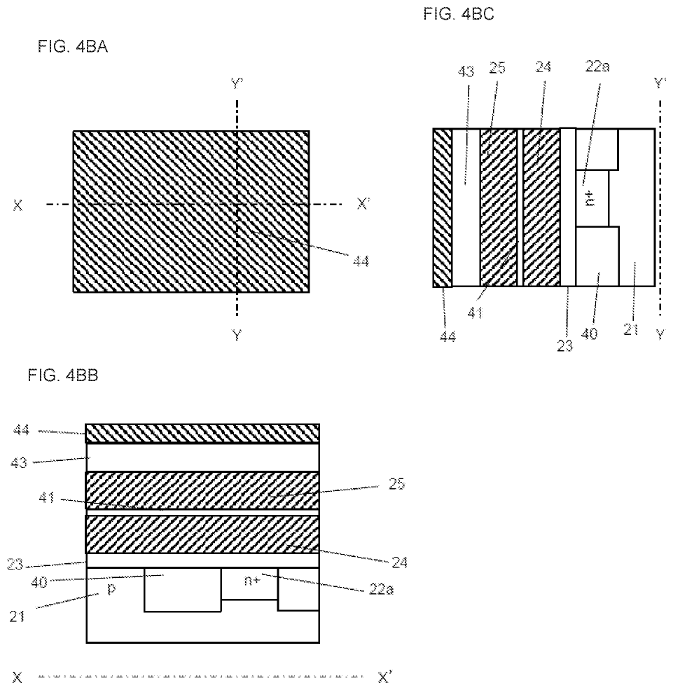

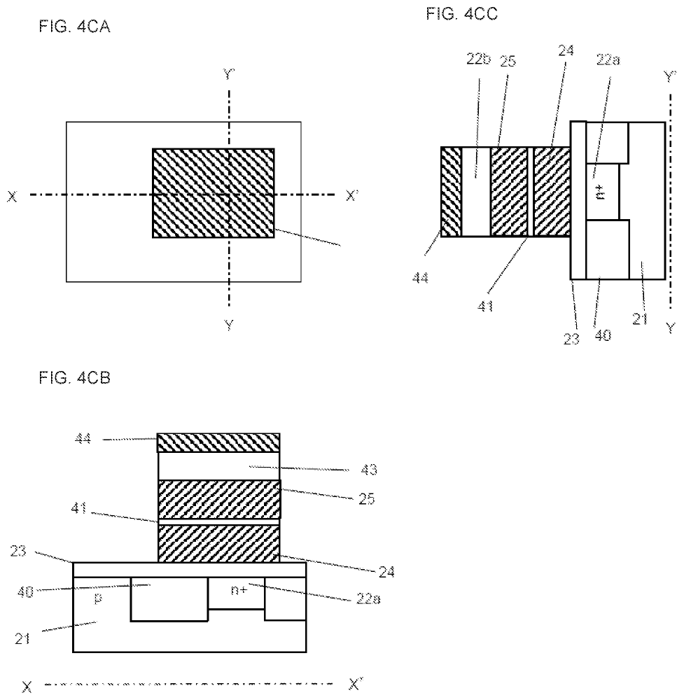

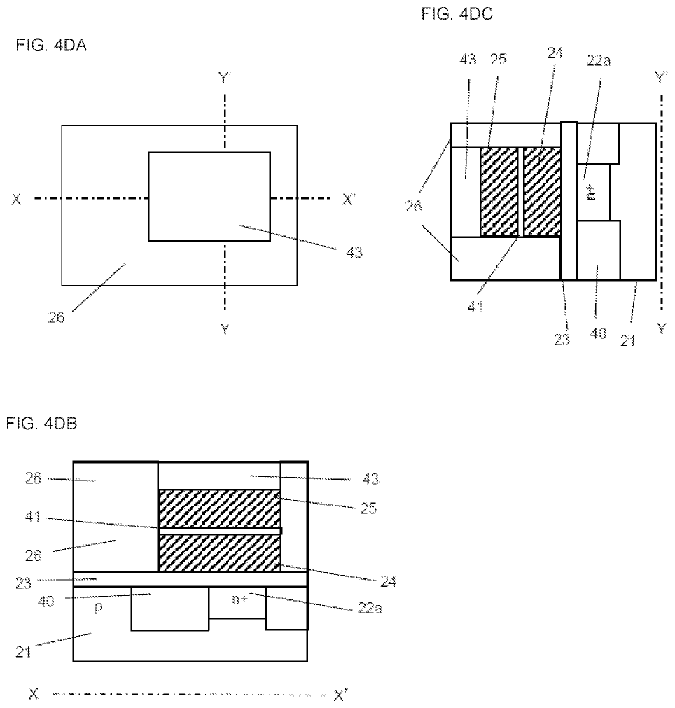

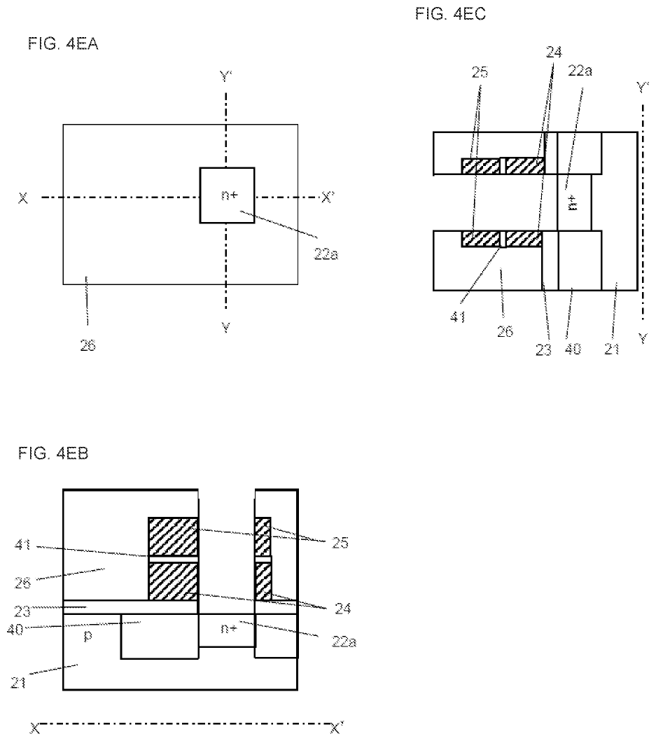

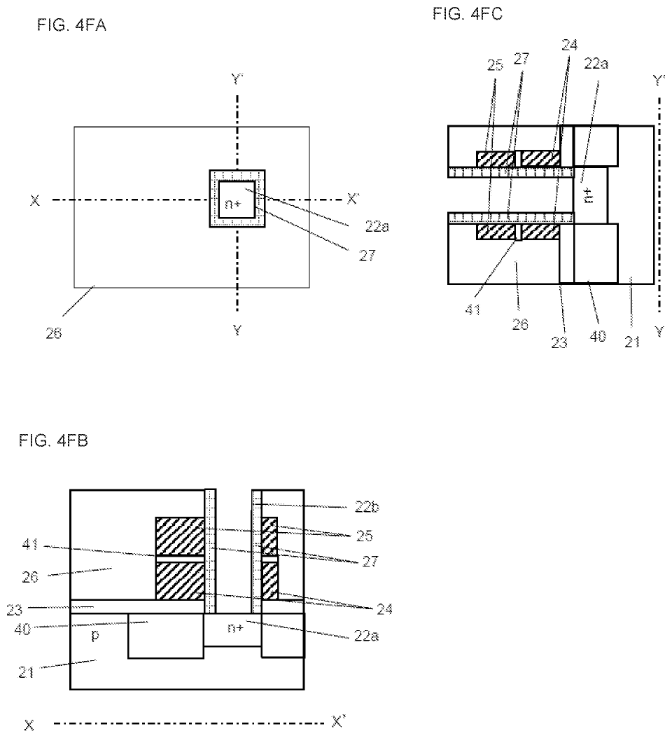

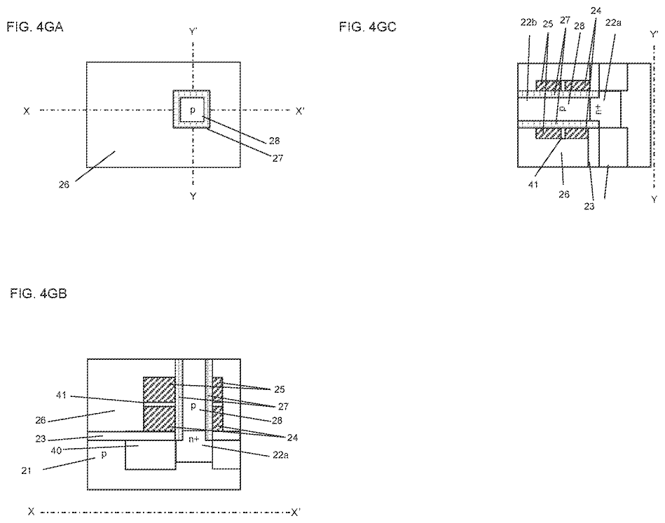

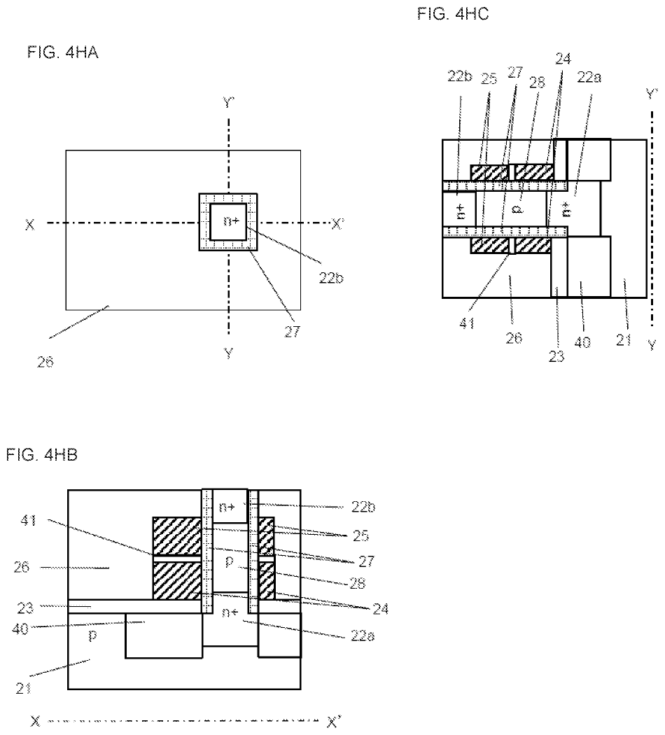

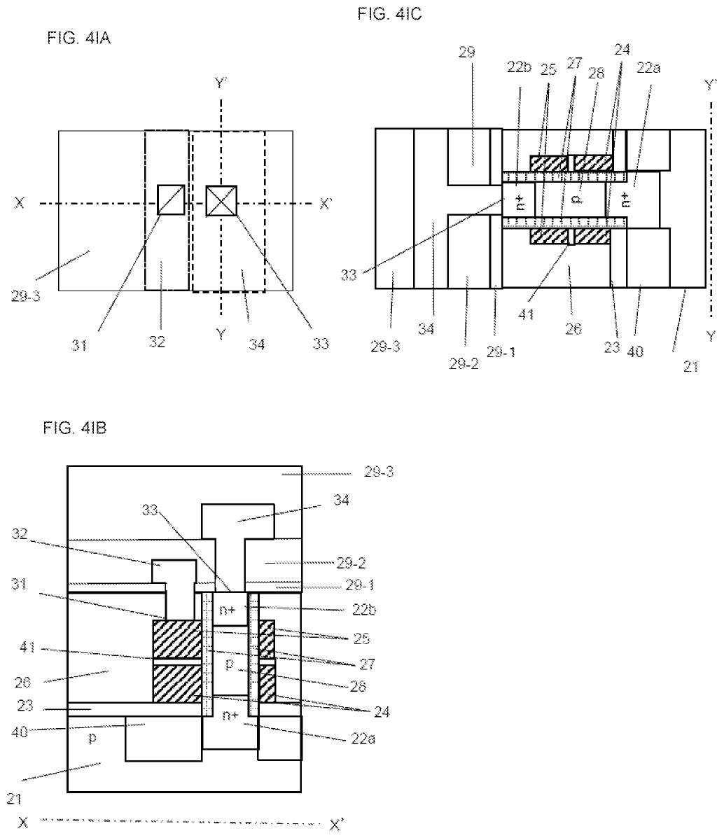

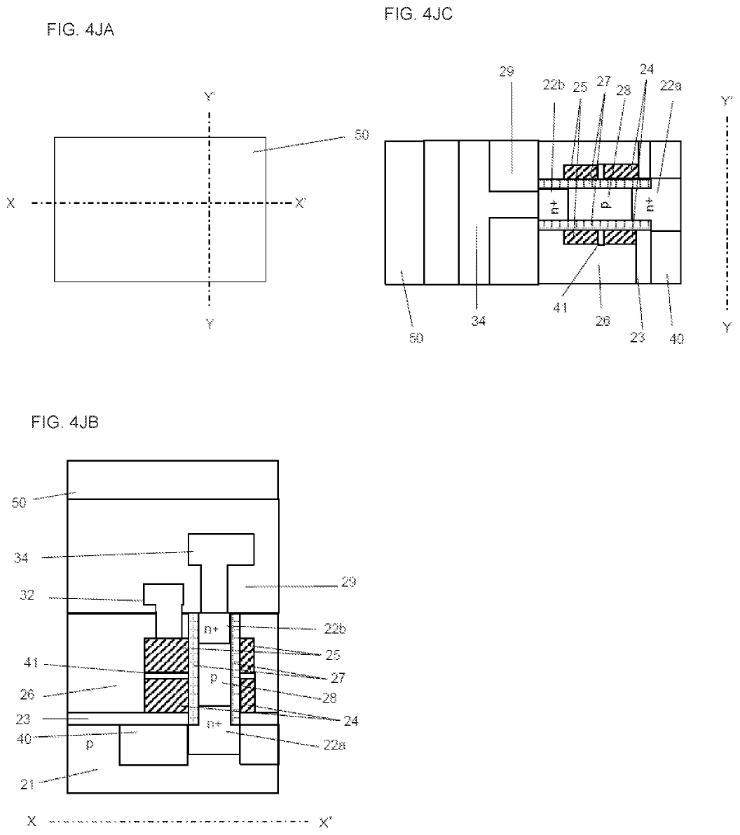

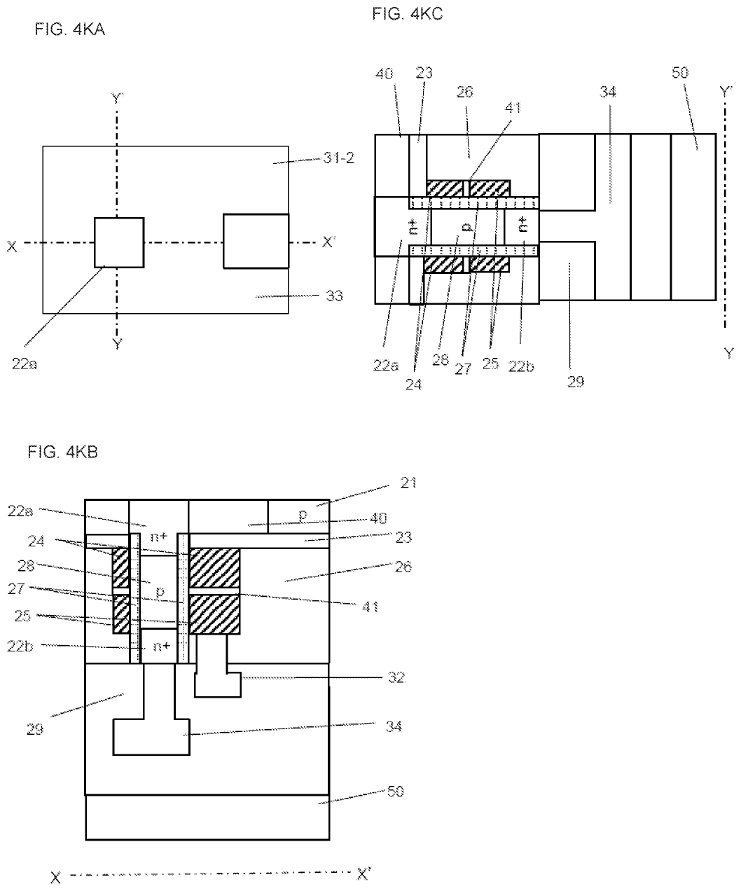

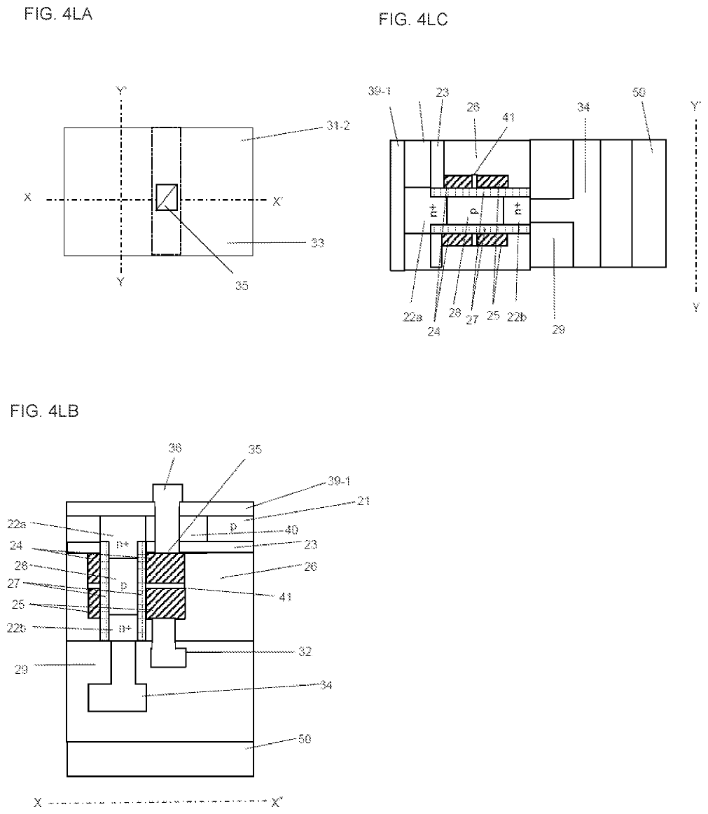

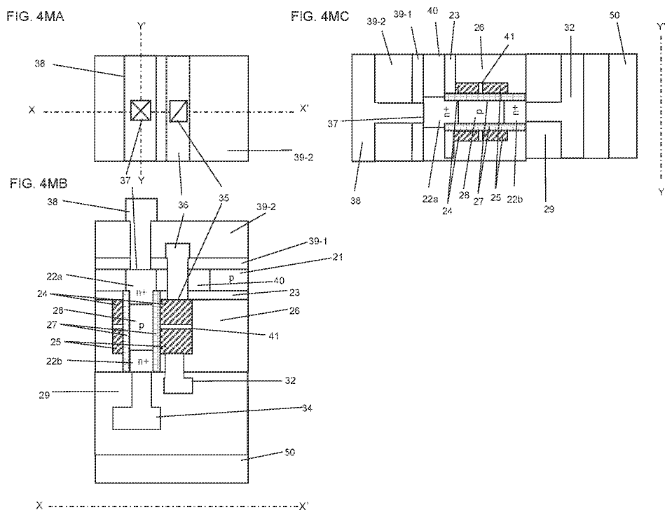

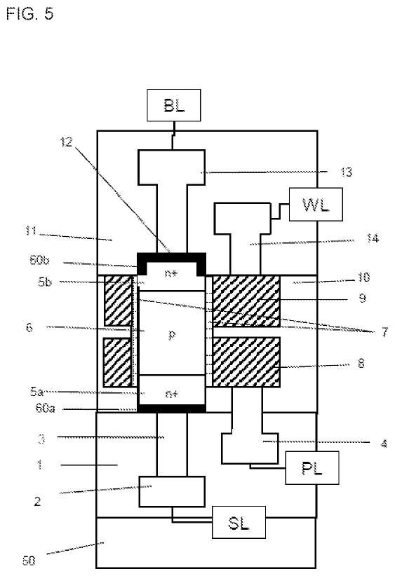

FIGS. 4JA, 4JB and 4JC are views for illustrating the method for producing the semiconductor device according to the first embodiment.

FIGS. 4KA, 4KB and 4KC are views for illustrating the method for producing the semiconductor device according to the first embodiment.

FIGS. 4LA, 4LB and 4LC are views for illustrating the method for producing the semiconductor device according to the first embodiment.

FIGS. 4MA, 4MB and 4MC are views for illustrating the method for producing the semiconductor device according to the first embodiment.

FIG. 5 illustrates a cross-sectional structure of a memory device with a semiconductor element according to a second embodiment in which electrodes are partially covered with metal films.

### DETAILED DESCRIPTION OF THE PREFERRED EMBODIMENTS

Hereinafter, a structure of a memory device with semiconductor elements, a driving scheme therefor, and a behavior of carriers stored therein according to the present invention will be described with reference to the drawings.

(First embodiment)

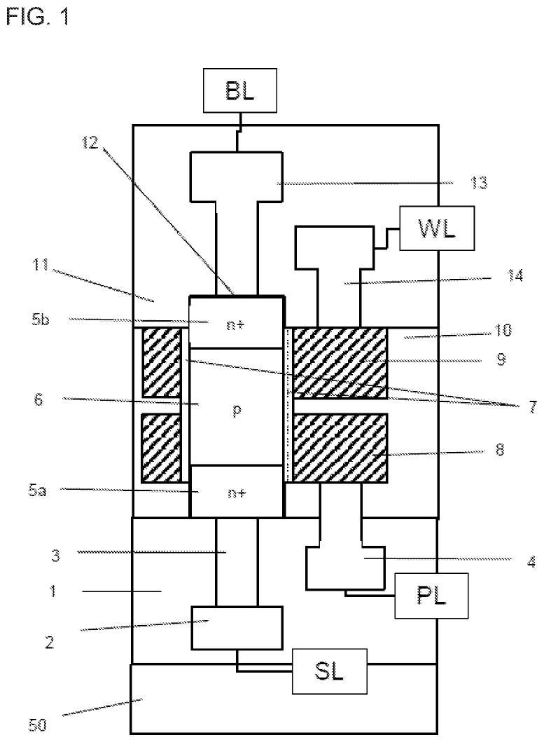

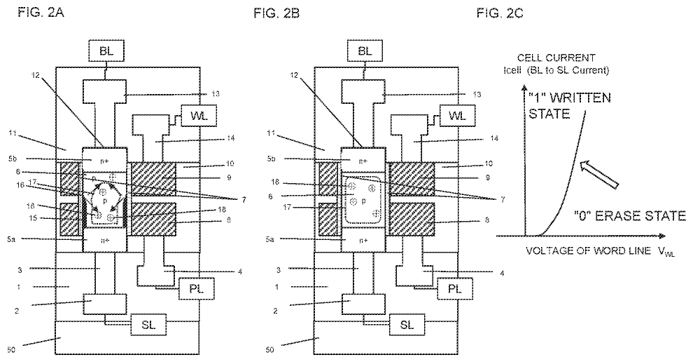

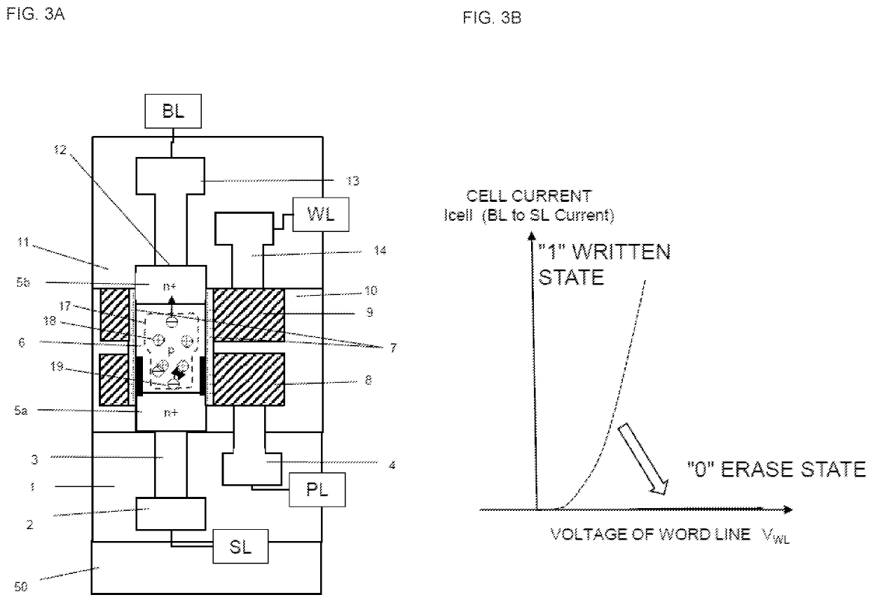

The structure and an operation mechanism of a memory cell with a semiconductor element according to a first embodiment of the present invention will be described with reference to FIGS. 1 to 3B. First, a memory cell structure with the semiconductor element according to the present embodiment will be described with reference to FIG. 1. Next, a mechanism of writing data to the memory with the semiconductor element, and the behavior of carriers therein will be described with reference to FIGS. 2A to 2C. Then, a mechanism of erasing data will be described with reference to FIGS. 3A and 3B.

FIG. 1 illustrates a cross-section of the structure of the semiconductor memory element according to the first embodiment of the present invention.

An insulating layer 1 (which is an example of a “first insulating layer” in the claims) is provided on a substrate 50 (which is an example of a “substrate” in the claims). A metal wire layer 2 (which is an example of a “first metal wire layer” in the claims) is provided such that it is embedded in the insulating layer 1 and extends in the horizontal direction with respect to the substrate 50. A metal wire layer 3 (which is an example of a “second metal wire layer” in the claims) is provided such that it is in contact with a top surface of the metal wire layer 2, extends in a vertical direction with respect to the substrate 50, and has a top surface located at the level of a top surface of the insulating layer 1. An n+layer 5a (which is an example of a “first impurity layer” in the claims) containing a high concentration of donor impurities (hereinafter, a semiconductor region containing a high concentration of donor impurities shall be referred to as an “n+ layer”) is provided in contact with the top surface of the metal wire layer 3. A pillar-shaped silicon p layer 6 (which is an example of a “first semiconductor pillar” in the claims) with p-type conductivity containing acceptor impurities is provided in contact with a top surface of the n+ layer 5a. A pillar-shaped n+ layer 5b (which is an example of a “second impurity layer” in the claims) containing donor impurities is provided in contact with the p layer 6. A gate insulating layer 7 (which is an example of a “gate insulating layer” in the claims) is provided covering a side face of the p layer 6 as well as part of side faces of the n+ layer 5a and the n+ layer 5b. A first gate conductor layer 8 (which is an example of a “first gate conductor layer” in the claims) is provided in contact with a side face of the gate insulating layer 7 and in proximity to the n+ layer 5a. A gate conductor layer 9 (which is an example of a “second gate conductor layer” in the claims) is provided not in contact with the gate conductor layer 8 but in contact with the side face of the gate insulating layer 7 and in proximity to the n+ layer 5b. An insulating layer 10 (which is an example of a “second insulating layer” in the claims) is provided partially covering the n+ layer 5a, the n+ layer 5b, the gate conductor layer 8, and the gate conductor layer 9. A metal wire layer 4 (which is an example of a “third metal wire layer” in the claims) is provided such that it is embedded in the insulating layer 10, extends in a horizontal direction with respect to the substrate 50, extends in the vertical direction with respect to the substrate 50, is in contact with the gate conductor layer 8, and is partially covered with the insulating layer 1 and the insulating layer 10. An insulating layer 11 (which is an example of a “third insulating layer” in the claims) is provided partially covering the n+ layer 5b and the gate conductor layer 9 and in contact with the insulating layer 10. A metal wire layer 13 (which is an example of a “fourth metal wire layer” in the claims) is provided in the insulating layer 11 such that it connects to the n+ layer 5b via a contact hole 12 (which is an example of a “contact hole” in the claims) and has a top surface extending in the insulating layer 11 in the horizontal direction with respect to the substrate 50. A metal wire layer 14 (which is an example of a “fifth metal wire layer” in the claims) is provided such that it is embedded in the insulating layer 11 and is connected to the gate conductor layer 9.

Accordingly, a dynamic flash memory cell is formed that includes the n+ layers 5a and 5b, the p layer 6, the gate insulating layer 7, the gate conductor layer 8, the gate conductor layer 9, and the metal wire layers 2, 3, 4, 13, and 14. The n+ layer 5a is connected to a source line SL (which is an example of a “source line” in the claims) via the metal wire layers 2 and 3. The n+ layer 5b is connected to a bit line BL (which is an example of a “bit line” in the claims) via the metal wire layer 13.

The gate conductor layer 8 is connected to a plate line PL (which is an example of a “plate line” in the claims) via the metal wire layer 4. The gate conductor layer 9 is connected to a word line WL (which is an example of a “word line” in the claims) via the metal wire layer 14. In an integrated circuit to which the memory device of the present embodiment is applied, the foregoing plurality of dynamic flash memory cells are arranged two-dimensionally on the substrate 50.

Although FIG. 1 illustrates the metal wire layer 2 such that its bottom surface is located lower than a top surface of the metal wire layer 4, the positional relationship may be opposite. This is also true of the relationship between the metal wire layers 13 and 14.

Any conductive material may be used for each of the metal wire layers 2, 3, 4, 13, and 14, such as a single metallic material, a metallic compound, or a multilayer structure of a plurality of materials.

Although the metal wire layer 2 connects to the n+layer 5a by penetrating the insulating layer 1 in FIG. 1, the metal wire layer 2 may be connected via the metal wire layer 4. The metal wire layer 2 and the metal wire layer 4 may be either the same conductor layer or different conductor layers.

Although the metal wire layers 2, 4, 13, and 14 are illustrated independently in FIG. 1, the metal wire layers 2, 4, 13, and 14 may be electrically connected together or connected together with a different metal wire layer added thereto.

Although the p layer 6 is a p-type semiconductor in FIG. 1, the concentration of the impurities therein may have a profile. Alternatively, the p layer 6 may be an n-type or i-type semiconductor.

When each of the n+ layer 5a and the n+ layer 5b is formed using a p+ layer containing holes as the majority carriers (hereinafter, a semiconductor region containing a high concentration of acceptor impurities shall be referred to as a “p+ layer”), forming the p layer 6 as an n-type semiconductor will allow the semiconductor element to function as a p-type semiconductor element.

For the substrate 50, any material, such as an in insulator or a semiconductor, can be used as long as it can be bonded to the insulating layer 1 and can support dynamic flash memory with a SGT structure.

Each of the gate conductor layer 8 and the gate conductor layer 9 may be either a heavily doped semiconductor layer or a conductor layer as long as it can change the potential of the p layer 6 via the gate insulating layer 7.

Although FIG. 1 illustrates each of the gate conductor layer 8 and the gate conductor layer 9 as being integral, such a gate conductor layer may be divided in the horizontal or vertical direction with respect to the substrate 50.

Although FIG. 1 illustrates each of the insulating layer 1, the insulating layer 10, and the insulating layer 11 as being integral, such an insulating layer may be formed using the same material or by combining a plurality of different materials in multiple layers.

The behavior of carriers, the storage of the carriers, and cell current during a write operation for the dynamic flash memory according to the first embodiment of the present invention will be described with reference to FIGS. 2A to 2C. As illustrated in FIG. 2A, first, a case will be described where the majority carriers in the n+ layer 5a and the n+ layer 5b are electrons, n+ poly (hereinafter, poly Si containing a high concentration of donor impurities shall be referred to as “n+ poly”) is used for the gate conductor layer 9 connecting to the metal wire layer 14 connected to the WL and for the gate conductor layer 8 connecting to the metal wire layer 4 connected to the PL, and a p-type semiconductor is used for the p layer 6. 0 V, for example, is input to the n+ layer 5a via the metal wire layers 2 and 3 connected to the source line SL. 3 V, for example, is input to the n+ layer 5b via the metal wire layer 13 connected to the bit line BL. 3 V, for example, is input to the gate conductor layer 8 via the metal wire layer 4 connected to the plate line PL. 1.5 V, for example, is input to the gate conductor layer 9 via the metal wire layer 14 connected to the word line WL.

In such a voltage applied state, electrons flow in a direction of the n+ layer 5b from the n+ layer 5a. An inversion layer 15 is formed immediately below the gate insulating layer 7, and further, an electric field becomes maximum at a pinch-off point 16 around the MOSFET including the gate conductor layer 9, and thus, an impact ionization phenomenon occurs in the region. Due to the impact ionization phenomenon, electrons accelerated toward the n+ layer 5b connected to the bit line BL from the n+ layer 5a connected to the source line SL collide with Si lattices, and electron-hole pairs are generated due to the kinetic energy. Some of the generated electrons flow into the gate conductor layer 9, but most of them flow into the n+ layer 5b connected to the bit line BL.

FIG. 2B illustrates holes 18 in the p layer 6 when all biases have become 0 V immediately after the writing. The generated holes 18 are the majority carriers in the p layer 6, and are temporarily stored in the p layer 6 surrounded by a depletion layer 17, and thus charge the p layer 6, which is substantially a substrate of the MOSFET including the gate conductor layer 8 and the gate conductor layer 9, in a positively biased manner in the non-equilibrium state. Consequently, the threshold voltage of the MOSFET including the gate conductor layer 9 becomes low due to the positive substrate bias effect because of the holes temporarily stored in the p layer 6. Accordingly, as illustrated in FIG. 2C, the threshold voltage of the MOSFET including the gate conductor layer 9 connecting to the word line WL becomes lower than that in the neutral state. Such a written state is allocated as logical memory data “1.”

It should be noted that the foregoing conditions of the voltages applied to the bit line BL, the source line SL, the word line WL, and the plate line PL are only examples for performing a write operation. Thus, other operating voltage conditions may be employed as long as a write operation can be performed. For example, when 3 V is applied to the bit line BL, 0 V is applied to the source line SL, 4 V is applied to the word line WL, and 1.5 V is applied to the plate line PL, the position of the pinch-off point 16 is shifted toward the gate conductor layer 8, but a similar phenomenon is allowed to occur. Meanwhile, when 3 V is applied to the bit line BL, 0 V is applied to the source line SL, 2 V is applied to the word line WL, and 2 V is applied to the plate line PL, the position of the pinch-off point 16 is shifted toward the gate conductor layer 9, but a similar phenomenon is still allowed to occur.

It is also possible to generate holes by flowing a gate induced drain leakage (GIDL) current instead of causing the foregoing impact ionization phenomenon to occur (for example, see E. Yoshida, T, Tanaka, “A Capacitorless 1T-DARM Technology Using Gate-Induced Drain-Leakage (GIDL) Current for Low-Power and High-Speed Embedded Memory”, IEEE Trans, on Electron Devices vol.53, pp.692-697 (2006)).

Next, the mechanism of an erase operation for the dynamic flash memory of the first embodiment illustrated in FIG. 1 will be described with reference to FIGS. 3A and 3B. In the state illustrated in FIG. 2B, a voltage of 0.6 V is applied to the bit line BL, a voltage of 0 V is applied to the source line SL, a voltage of 2 V is applied to the plate line PL, and a voltage of 0 V is applied to the word line WL. Consequently, since the concentration of the holes 18 stored in the player 6 is sufficiently higher than the concentration of holes in the n+ layer 5a, the holes flow into the n+ layer 5a due to diffusion because of the concentration gradient. Conversely, since the concentration of electrons in the n+ layer 5a is higher than the concentration of electrons in the p layer 6, electrons 19 flow into the player 6 due to diffusion because of the concentration gradient. The electrons that flow into the p layer 6 recombine with the holes in the p layer 6, and thus disappear. However, not all of the injected electrons 19 disappear, and the electrons 19 that have not disappeared pass through the depletion layer 17 by drifting due to the potential gradient between the bit line BL and the source line SL, and then flow into the n+ layer 5b. Since the electrons are continuously supplied from the source line SL, excess holes recombine with the electrons in quite a short time, and thus return to the initial state. Accordingly, as illustrated in FIG. 3B, the threshold voltage of the MOSFET including the gate conductor layer 9 connecting to the word line WL returns to the original level. Such an erase state of the memory element corresponds to logical memory data “0.”

It should be noted that the voltage applied to the bit line is adjustable to be even higher or lower than 0.6 V as long as it can cause drift of electrons. As another method of erasing data, the foregoing conditions of the voltages applied to the bit line BL, the source line SL, the word line WL, and the plate line PL may be other combinations, such as 0.6 V (BL)/0 V (SL)/0 V (PL)/2 V (WL), 0 V (BL)/0.6 V (SL)/1 V (PL)/0 V (WL), and −0.6 V (BL)/0 V (SL)/1 V (PL)/0 V (WL). The foregoing conditions of the voltages applied to the bit line BL, the source line SL, the word line WL, and the plate line PL are only examples for performing an erase operation. Thus, other operating voltage conditions may be employed as long as an erase operation can be performed.

A method for producing the semiconductor device according to the present embodiment will be described with reference to FIGS. 4AA to 4MC (hereinafter also collectively referred to as “FIGS. 4”). FIGS. 4AA to 4MA are plan views, FIGS. 4AB to 4MB are vertical cross-sectional views along line X-X′ in FIGS. 4AA to 4MA, and FIGS. 4AC to 4MC are vertical cross-sectional views along line Y-Y′ in FIGS. 4AA to 4MA.

As illustrated in FIGS. 4AA to 4AC, an insulating film 40 for element isolation is formed on a p-type semiconductor substrate 21. Next, an n+ layer 22a is formed in a region where a memory element is to be formed. It should be noted that any insulating material may be used for the insulating film 40 as long as it has etching selectivity with respect to the semiconductor substrate when the substrate is polished from its back side later. It should be also noted that the p-type substrate 21 may be a p-well layer formed in an n-type semiconductor substrate. Then, a silicon oxide film 23 is formed on the entire surface of the substrate.

Next, as illustrated in FIGS. 4BA to 4BC, a phosphorus-doped polysilicon film 24, a silicon oxide film 41, a phosphorus-doped polysilicon film 25, a silicon oxide film 43, and a silicon nitride film 44 are formed in this order on the silicon oxide film 23. Any material may be used for the silicon nitride film 44 as long as it serves as a mask material in an etching process, such as RIE (reactive ion etching), and has etching selectivity with respect to a silicon oxide film or silicon. In addition, any conductive material may be used for each of the polysilicon films 24 and 25 as long as it becomes a material for a gate electrode later, and can withstand the thermal history of the following processes.

Next, as illustrated in FIGS. 4CA to 4CC, the silicon oxide films 41 and 43 and the polysilicon films 24 and 25 are etched with the RIE method using the silicon nitride film 44 as a mask material so as to leave a gate electrode portion.

Next, as illustrated in FIGS. 4DA to 4DC, an insulating layer 26 (not illustrated) is formed on the entire surface using the CVD (chemical vapor deposition) method, for example. Then, the insulating layer 26 is polished using the CMP (chemical mechanical polishing) technology so as to expose the surface of the mask material 44, and further, the mask material 44 is selectively removed. Furthermore, etching is performed through CMP so as to planarize the insulating layer 26 and the silicon oxide film 43. Although FIGS. 4DA to 4DC illustrate the insulating layer 26 and the silicon oxide film 43 separately, the insulating layer 26 and the silicon oxide film 43 shall be collectively illustrated as the insulating layer 26 hereinafter.

Next, as illustrated in FIGS. 4EA to 4EC, the insulating layer 26, the insulating layer 41, the polysilicon layers 24 and 25, and the silicon oxide film 23 in a portion where the memory element is to be formed is etched through RIE so as to expose the surface of the n+layer 22a and thus form a groove.

Next, as illustrated in FIGS. 4FA to 4FC, an oxide film (not illustrated) is entirely formed on the entire surface using the ALD (atomic layer deposition) technology, for example, and is then etched back, whereby the resulting oxide film remains only on a sidewall of the groove formed in FIGS. 4EA to 4EC. Thus, a gate insulating film 27 is formed.

Next, as illustrated in FIGS. 4GA to 4GC, a p layer 28 is grown using the selective CVD method, for example, under the condition that the p layer 28 becomes a crystalline layer continuous with the n+layer 22a. Then, portions of the p layer 28 other than those necessary to operate as a memory cell are removed. It should be noted that the p layer 28 may be formed using other methods, such as the selective epitaxial crystal growth method.

Next, as illustrated in FIGS. 4HA to 4HC, an n+ layer 22b is formed on the p layer 28. In addition, the n+ layer 22a diffuses upward from below the p layer 28 due to the thermal history of the processes in FIGS. 4GA to 4GC, FIGS. 4HA to 4HC, and the like.

Next, as illustrated in FIGS. 4IA to 4IC, an insulating layer 29-1 is formed on the entire surface, and then, a contact hole 31 is formed. After that, a metal wire layer 32 is formed. Further, an insulating layer 29-2 is formed on the entire surface, and then, a contact hole 33 is formed to form a metal wire layer 34. After that, an insulating layer 29-3 is formed on the entire surface. Although FIGS. 4IA to 4IC illustrate the insulating layers 29-1, 29-2, and 29-3 separately, such layers shall be collectively illustrated as the insulating layer 29 hereinafter. In addition, although FIGS. 4IA to 4IC illustrate a method of forming the contact hole 33 to directly connect a metal wire layer to the n+ layer 22b, it is also possible to use a method of directly connecting the metal wire layer 34 via the contact hole 31 and the metal wire layer 32. Although the contact holes and the metal wire layers are not actually visible in plan view, the plan view of FIG. 4IA illustrates the contact holes 31 and 33 and the metal wire layers 32 and 34 for easy understanding.

Next, as illustrated in FIGS. 4JA to 4JC, the substrate 50 is attached to the insulating layer 29 through room-temperature bonding. It should be noted that any of metal, semiconductors, insulators, or other materials may be used for the substrate as long as such materials serve as the base of the semiconductor memory element to be formed, and can withstand the following wiring process.

Next, as illustrated in FIGS. 4KA to 4KC, the stack illustrated in FIGS. 4JA to 4JC is flipped upside down so that the substrate 50 becomes the bottom face and the p layer 21 becomes the front face. Then, the p layer 21 is polished using the CMP technology so as to expose the surface of the insulating layer 40.

Next, as illustrated in FIGS. 4LA to 4LC, an insulating layer 39-1 is formed on the entire surface. Then, a contact hole 35 is formed. After that, a metal wire layer 36 is formed.

Next, as illustrated in FIGS. 4MA to 4MC, an insulating layer 39-2 is formed on the entire surface. Then, a contact hole 37 is formed. After that, a metal wire layer 38 is formed. Accordingly, a dynamic flash memory element is formed on the substrate 50. Although FIGS. 4MA to 4MC illustrate a method of forming the contact hole 37 to directly connect a wire layer to the n+layer 22a, it is also possible to use a method of connecting the metal wire layer 38 via the contact hole 35 and the metal wire layer 36. Although the contact holes 35 and 37 and the metal wire layer 36 are not actually visible in plan view, the plan view of FIG. 4MA illustrates the contact holes 35 and 37 and the metal wire layer 36 for easy understanding.

Although the present embodiment illustrates the p layer 28 and the impurity layers 22a and 22b as having a pillar shape with a quadrangular bottom face, such layers may have a pillar shape with a polygonal, rectangular, elliptical, or circular bottom face.

Although a phosphorus-doped polysilicon layer is used as each of the gate conductor layers 24 and 25, any conductive material, such as metal, alloy, or metal compounds, may be used as long as such a material can withstand the thermal process following the formation of the gate conductor layers 24 and 25. In addition, different materials may be used for the gate conductor layers 24 and 25.

For the gate insulating film 27, any insulating film used in the common MOS process can be used, such as a SiO2 film, a SiON film, a HfSiON film, or a stacked film of SiO2/SiN, for example.

Although an example in which a silicon oxide film is used for the insulating film 41 is illustrated herein, any insulating film used in the common MOS process can be used, such as a SiON film, a HfSiON film, or a stacked film of SiO2/SiN, for example.

Although FIGS. 4EA to 4GC illustrate a method in which the polysilicon layers (i.e., the gate conductor layers) 24 and 25, the gate insulating film 27, and the p layer 28 are formed in this order, the order of the layers can be freely changed by utilizing a method of forming various dummy films and also utilizing a selective etching process.

Although FIGS. 4 representing an example of the present invention illustrate the metal wire layers, all of which extend in the vertical direction with respect to the X-X′ axis, the metal wire layers may be extended in a parallel direction or in a diagonal direction. That is, the metal wire layers can be freely arranged as seen in plan view.

Either the same material or a combination of different materials may be used for the insulating films 29-1, 29-2, 29-3, 39-1, and 39-2 illustrated in FIGS. 4 as long as such materials have an electrically insulating property.

Referring to FIGS. 4MA to 4MC in conjunction with FIG. 1, the metal wire layer 32 connects to the plate line, the metal wire layer 34 connects to the source line, the metal wire layer 36 connects to the word line, and the metal wire layer 38 connects to the bit line. However, the metal wire layer 32 may connect to the word line, the metal wire layer 34 may connect to the bit line, the metal wire layer 36 may connect to the plate line, and the metal wire layer 38 may connect to the source line.

The present embodiment has the following features.

(Feature 1)

In the dynamic flash memory with the SGT structure according to the first embodiment of the present invention, low-resistance metal wiring can be made on each of the bit line BL side and the source line SL side. This can reduce parasitic resistance, contributing to a high-speed operation of the memory. In addition, since there is little unbalanced parasitic resistance on opposite sides of the memory element, it is possible to increase the voltage margin for the memory operation. Further, since low-resistance wires can be arranged at positions near each cell, it is possible to connect more cells in common to the bit line or the source line without sacrificing the cell areas as compared to the conventional technology.

(Feature 2)

In the dynamic flash memory with the SGT structure according to the first embodiment of the present invention, the wire connecting to the source line and the wire connecting to the bit line can be arranged on opposite sides of the memory element portion. Thus, the contact holes and the wires can be arranged in an overlapped manner in the planar layout, which can significantly improve the flexibility of the wire layout as compared to the conventional technology. Further, regarding the wire connecting to the word line and the wire connecting to the plate line that are necessary for the dynamic flash memory, the contact holes and the wires can also be arranged in an overlapped manner in the planar layout, which can significantly improve the flexibility of the wire layout as compared to the conventional technology. Besides, connection of wires to other electrodes, interconnection of wires, and the like can be made freely in both directions. Thus, metal wiring can be made with higher flexibility than with the conventional technology, whereby a memory element with higher density can be provided.

(Second embodiment)

A semiconductor device of a second embodiment of the present invention will be described with reference to FIG. 5. In FIG. 5, components identical to or similar to those in FIG. 1 are denoted by identical reference signs.

As illustrated in FIG. 5, the n+ layers 5a and 5b in FIG. 1 are respectively partially covered with metal films 60a and 60b (which are examples of a “first metal film” in the claims). Accordingly, a semiconductor device with parasitic resistance further reduced than that in the first embodiment can be provided.

It should be noted that either metal or silicide may be used for each of the metal films 60a and 60b as long as it has a metallic property. In addition, a multilayer structure of metal films may be used.

Although both the impurity layers 5a and 5b are respectively partially covered with the metal films 60a and 60b in FIG. 5, a metal film may be formed only on one of the surfaces of the impurity layers 5a and 5b.

Although only the surface of the n+ layer 5a is covered with the metal film 60a, while both the surface and the side faces of the n+ layer 5b are covered with the metal film 60b in FIG. 5, any structure is acceptable as long as one or each of the impurity layers is partially covered with a metal film.

The present embodiment has the following feature.

(Feature 1)

In the semiconductor device according to the second embodiment of the present invention, the metal layers 60a and 60b are formed on the respective surfaces of the n+ layers 5a and 5b so that the effective contact resistance between the metal wire layer 2 and the n+ layer 5a and between the metal wire layer 13 and the n+ layer 5b can be reduced. Thus, a semiconductor memory element with parasitic resistance further reduced than that in the first embodiment can be provided.

The present invention can be implemented in various embodiments and modifications without departing from the broad spirit and scope of the present invention. In addition, each of the foregoing embodiments only describes an example of the present invention and is not intended to limit the scope of the present invention. The foregoing examples and modified examples can be combined as appropriate. Further, even if some of the components of the foregoing embodiments are removed as needed, the resulting structure is within the technical idea of the present invention.

With the semiconductor element according to the present invention, it is possible to provide a semiconductor circuit with a SGT structure having higher density than that of the conventional technology.

What is claimed is:

1. A semiconductor device comprising a memory cell, the memory cell including:
a first insulating layer on a substrate;
a first metal wire layer embedded in the first insulating layer, the first metal wire layer extending in a horizontal direction with respect to the substrate;
a second metal wire layer in contact with the first metal wire layer, the second metal wire layer extending in a vertical direction with respect to the substrate and having a top surface located at a level of a top surface of the first insulating layer;
a first impurity layer in contact with the second metal wire layer, the first impurity layer extending upward;
a first semiconductor pillar in contact with the first impurity layer, the first semiconductor pillar extending upward;
a second impurity layer continuous with a top portion of the first semiconductor pillar, the second impurity layer extending upward;
a gate insulating layer covering a side face of the first semiconductor pillar, at least part of a side face of the first impurity layer, and at least part of a side face of the second impurity layer;
a first gate conductor layer in contact with a side face of the gate insulating layer and in proximity to the first impurity layer;
a second gate conductor layer not in contact with the first gate conductor layer but in contact with the side face of the gate insulating layer and in proximity to the second impurity layer;
a second insulating layer partially covering the first impurity layer, the second impurity layer, the first gate conductor layer, and the second gate conductor layer;
a third metal wire layer embedded in the first insulating layer, the third metal wire layer extending in the horizontal direction with respect to the substrate, extending in the horizontal direction in the second insulating layer, and being in contact with the first gate conductor layer;
a third insulating layer partially covering the second impurity layer and the second gate conductor layer, the third insulating layer being in contact with the second insulating layer;
a fourth metal wire layer connected to the second impurity layer via a contact hole formed in the third insulating layer, the fourth metal wire layer extending in the horizontal direction on or in the third insulating layer; and
a fifth metal wire layer connected to the second gate conductor layer.

2. The semiconductor device according to claim 1, wherein one or each of the first metal wire layer, the third metal wire layer, the fourth metal wire layer, and the fifth metal wire layer is shared by a plurality of memory cells.

3. The semiconductor device according to claim 1, wherein:
a memory write operation is performed by controlling a voltage applied to each of the first metal wire layer, the second metal wire layer, the third metal wire layer, the fourth metal wire layer, and the fifth metal wire layer to perform an operation of generating electrons and holes in the first semiconductor pillar and/or the second impurity layer through an impact ionization phenomenon based on a current flowing between the first impurity layer and the second impurity layer or using a gate induced drain leakage current, to perform an operation of removing, from among the generated electrons and holes, the electrons or the holes that are minority carriers in the first semiconductor pillar and the second impurity layer, and to perform an operation of causing some or all of the electrons or the holes that are majority carriers in the first semiconductor pillar to remain in the first semiconductor pillar, and
a memory erase operation is performed by controlling a voltage applied to each of the first metal wire layer, the third metal wire layer, the fourth metal wire layer, and the fifth metal wire layer to cause carriers remaining in the first semiconductor pillar to return to an equilibrium state.

4. The semiconductor device according to claim 1, wherein:
one of the second metal wire layer connecting to the first impurity layer or the fourth metal wire layer connecting to the second impurity layer is a source line, and another is a bit line,
one of the third metal wire layer connecting to the first gate conductor layer or the fifth metal wire layer connecting to the second gate conductor layer is a plate line, and another is a word line, and
memory writing and/or erasing are/is performed by applying a voltage to each of the source line, the bit line, the plate line, and the word line.

5. The semiconductor device according to claim 1, wherein majority carriers in the first impurity layer are electrons, and majority carriers in the first semiconductor pillar are holes.

6. The semiconductor device according to claim 1, wherein majority carriers in the first impurity layer are holes, and majority carriers in the first semiconductor pillar are electrons.

7. The semiconductor device according to claim 1, wherein at least one of the first gate conductor layer or the second gate conductor layer is divided into two or more regions as seen in plan view.

8. The semiconductor device according to claim 1, wherein:
the first metal wire layer and the fourth metal wire layer are arranged in a direction perpendicular to an interface between the contact hole and the second impurity layer, and
the first semiconductor pillar is present between the first metal wire layer and the fourth metal wire layer.

9. The semiconductor device according to claim 1, wherein a surface of at least one of the first impurity layer or the second impurity layer is partially covered with a first metal film.
